(19) United States
(12) Patent Application Publication
(10) Pub. No.: US 2026/0013292 A1
(43) Pub. Date: Jan. 8, 2026

(54) DISPLAY APPARATUS, METHOD OF MANUFACTURING DISPLAY APPARATUS, AND ELECTRONIC DEVICE

(71) Applicant: Samsung Display Co., Ltd., Yongin-Si (KR)

(72) Inventors: Hyunggi Jung, Yongin-si (KR); Donghan Kim, Yongin-si (KR); Youngseok Park, Yongin-si (KR); Seungbo Shim, Yongin-si (KR); Soonchang Yeon, Yongin-si (KR)

(21) Appl. No.: 19/004,588

(22) Filed: Dec. 30, 2024

(30) Foreign Application Priority Data
Jul. 8, 2024 (KR) 10-2024-0089722

(51) Int. Cl. H10H 29/37; H10H 29/01; H10H 29/855

(52) U.S. Cl. CPC H10H 29/37; H10H 29/012; H10H 29/8552

(57) ABSTRACT

A display apparatus is disclosed that includes a substrate, a pixel electrode disposed on the substrate, a first bank layer disposed on the pixel electrode, and having a first opening overlapping a central portion of the pixel electrode and a protrusion and a recess that are adjacent to the first opening, a capping layer disposed above or below the first bank layer and having a second opening overlapping the first opening of the first bank layer, an intermediate layer disposed on the pixel electrode and the first bank layer and including at least one emission layer and at least one functional layer, and a counter electrode disposed on the intermediate layer.

### CROSS-REFERENCE TO RELATED APPLICATION

This application is based on and claims priority under 35 U.S.C. § 119 to Korean Patent Application No. 10-2024-0089722, filed on Jul. 8, 2024, in the Korean Intellectual Property Office, the disclosure of which is incorporated by reference herein in its entirety.

### BACKGROUND

### 1. Field

The present disclosure relates to a display apparatus and a method of manufacturing the same, and more particularly, to a display apparatus including a light-emitting diode. The present disclosure relates to an electronic device including a display apparatus.

### 2. Description of the Related Art

An electronic device may include a display apparatus visually displaying data. Generally, display apparatuses include a substrate divided into a display area and a non-display area. In a light emitting diode display, a plurality of pixels may be arranged in the display area. The display area includes thin film transistors corresponding to the respective pixels, which are electrically connected to pixel electrodes of light emitting diodes. Each of the light emitting diodes includes a pixel electrode, a counter electrode, and an emission layer between the pixel electrode and the counter electrode. Generally, the non-display area includes various wirings for transmitting electrical signals to the display area, drivers, controllers, and the like. As the uses of display apparatuses have become more diversified, various efforts have been made to improve the quality of images produced by display apparatuses.

### SUMMARY

A bank layer including an opening overlapping a pixel electrode may be arranged on the pixel electrode. An emission layer and a functional layer may be arranged between the bank layer and a counter electrode. The bank layer may include a recess and a protrusion, which may perform various functions. The bank layer including the recess and the protrusion may be formed through one process. In this case, there may be various issues including shape precision of the recess and the protrusion.

Additional aspects will be set forth in part in the description which follows and, in part, will be apparent from the description, or may be learned by practice of the presented embodiments of the disclosure.

According to one or more embodiments, a display apparatus includes a substrate, a pixel electrode disposed on the substrate, a first bank layer disposed on the pixel electrode, and having a first opening overlapping a central portion of the pixel electrode and a protrusion and a recess that are adjacent to the first opening, a capping layer disposed above or below the first bank layer and having a second opening overlapping the first opening of the first bank layer, an intermediate layer disposed on the pixel electrode and the first bank layer and including at least one emission layer and at least one functional layer, and a counter electrode disposed on the intermediate layer.

The capping layer may be disposed on the first bank layer, and the capping layer may have a third opening overlapping the recess of the first bank layer.

The third opening may cross the capping layer in a thickness direction of the capping layer.

The capping layer may be in contact with an upper surface of the pixel electrode within the first opening of the first bank layer.

The first bank layer may include a light-shielding material, and the capping layer may include an inorganic insulating material.

The capping layer may be disposed below the first bank layer, and the display apparatus may further include a second bank layer disposed below the capping layer.

The second bank layer may cover an edge of the pixel electrode, and the capping layer may entirely cover the second bank layer.

An edge of the capping layer, defining the second opening, may be in contact with an upper surface of the pixel electrode, and an edge of the first bank layer, defining the first opening, may be spaced apart from the upper surface of the pixel electrode.

The recess may cross the first bank layer in a thickness direction of the first bank layer, and the capping layer may have a third opening overlapping the recess.

The second bank layer may include a light-shielding material, and the capping layer may include an inorganic insulating material.

According to one or more embodiments, a method of manufacturing a display apparatus includes disposing a pixel electrode on a substrate, forming, on the pixel electrode, a first bank layer having a first opening overlapping a central portion of the pixel electrode and a protrusion and a recess that are adjacent to the first opening, and forming, above or below the first bank layer, a capping layer having a second opening overlapping the first opening of the first bank layer, wherein the first opening, the protrusion, and the recess of the first bank layer are formed substantially simultaneously.

The capping layer may be formed on the first bank layer, and the method may further include forming a third opening overlapping the recess, in the capping layer.

The capping layer may be formed to cover an edge of the first bank layer, the edge defining the first opening.

The third opening may cross the capping layer in a thickness direction of the capping layer, and the method may further include extending the recess of the first bank layer in a thickness direction of the first bank layer.

The capping layer may be formed below the first bank layer, and the method may further include forming a second bank layer below the capping layer.

The second bank layer may cover an edge of the pixel electrode, and the capping layer may entirely cover the second bank layer.

An edge of the capping layer, defining the second opening, may be in contact with an upper surface of the pixel electrode, and an edge of the first bank layer, the edge defining the first opening, may be spaced apart from the upper surface of the pixel electrode.

The recess may be formed across the first bank layer in a thickness direction of the first bank layer, and the method may further include forming a third opening overlapping the recess, in the capping layer.

The third opening may be formed across the capping layer in a thickness direction of the capping layer, and the method may further include forming a groove overlapping the recess and the third opening in the second bank layer.

The forming of the first bank layer may include pressing the first bank layer attached to a mold onto the pixel electrode.

According to one or more embodiments, an electronic device includes a display apparatus, wherein the display apparatus includes a substrate, a pixel electrode disposed on the substrate, a first bank layer disposed on the pixel electrode, and having a first opening overlapping a central portion of the pixel electrode and a protrusion and a recess that are adjacent to the first opening, a capping layer disposed above or below the first bank layer and having a second opening overlapping the first opening of the first bank layer, an intermediate layer disposed on the pixel electrode and the first bank layer and including at least one emission layer and at least one functional layer, and a counter electrode disposed on the intermediate layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a schematic plan view illustrating a display apparatus according to an embodiment;

FIG. 1B is a perspective view illustrating an electronic device according to an embodiment.

FIG. 1C is a perspective view illustrating an electronic device according to an embodiment.

FIG. 1D is a perspective view illustrating an electronic device according to an embodiment.

FIG. 2 is a cross-sectional view showing a portion of a display apparatus according to an embodiment;

FIG. 3 is an enlarged cross-sectional view of a portion of a display apparatus according to an embodiment;

FIG. 4 is an enlarged cross-sectional view of a portion of a display apparatus according to an embodiment;

FIGS. 5A, 5B, 5C, 5D, 5E, and 5F are schematic cross-sectional views illustrating a method of manufacturing a display apparatus according to an embodiment;

FIG. 6 is a schematic cross-sectional view illustrating an operation of a method of manufacturing a display apparatus according to an embodiment;

FIG. 7 is a cross-sectional view of a portion of a display apparatus according to an embodiment;

FIG. 8 is an enlarged cross-sectional view of a portion of a display apparatus according to an embodiment;

FIG. 9 is an enlarged cross-sectional view of a portion of a display apparatus according to an embodiment;

FIG. 10 is an enlarged cross-sectional view of a portion of a display apparatus according to an embodiment;

FIGS. 11A, 11B, and 11C are schematic cross-sectional views illustrating a method of manufacturing a display apparatus according to an embodiment;

FIGS. 12A, 12B, and 12C are schematic cross-sectional views illustrating a method of manufacturing a display apparatus according to an embodiment; and

FIG. 13 is a schematic cross-sectional view illustrating an operation of a method of manufacturing a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating embodiments are referred to gain a sufficient understanding of embodiments, the merits thereof, and the objectives accomplished by the implementation of the disclosure. However, the disclosure is not limited to the embodiments disclosed below, but may be implemented in various different forms.

Hereinafter, embodiments will be described in detail with reference to the attached drawings. The same reference numerals in the drawings denote like elements, and a repeated explanation thereof will not be given.

In this specification, terms such as first and second are used for the purpose of distinguishing one component from another component without a limiting meaning.

In the following embodiments, the singular expressions in the present specification include the plural expressions unless clearly specified otherwise in context.

In this specification, terms such as “comprise,” “include,” and “have” (as well as their variations such as “comprising”) represent that the features or elements described in the specification do not preclude the possibility of one or more additional features or elements.

In the following embodiments, when a portion such as a film, a region, and a component is referred to as being above or on other portions, this includes the case in which the portion is directly on other portions as well as the case in which other films, other films, and components are located therebetween.

For convenience of explanation, in the drawings, the size of components may be exaggerated or reduced. Sizes and thicknesses of the elements shown in the drawings are for the purpose of descriptive convenience, and thus the disclosure is not necessarily limited thereto.

When an embodiment is otherwise embodied, a certain process order may be performed differently from the described order. For example, two processes described in succession may be performed substantially simultaneously, or may be performed in an order opposite to the order described.

In this specification, when films, regions, components, and the like are connected, this includes the case in which films, regions, and components are directly connected, or the case in which other films, regions, and components are located between the films, regions, and components. For example, when a film, a region, a component, and the like are electrically connected in this specification, this represents the case in which a film, a region, a component, and the like are directly electrically connected, or indirect electrical connection in which another film, region, component, and the like are located therebetween.

The x-axis, y-axis, and z-axis are not limited to the three axes of the orthogonal coordinate system, and may be interpreted in a broad sense including them. For example, the x-axis, y-axis, and z-axis may be orthogonal to each other, but may refer to different directions that are not orthogonal to each other.

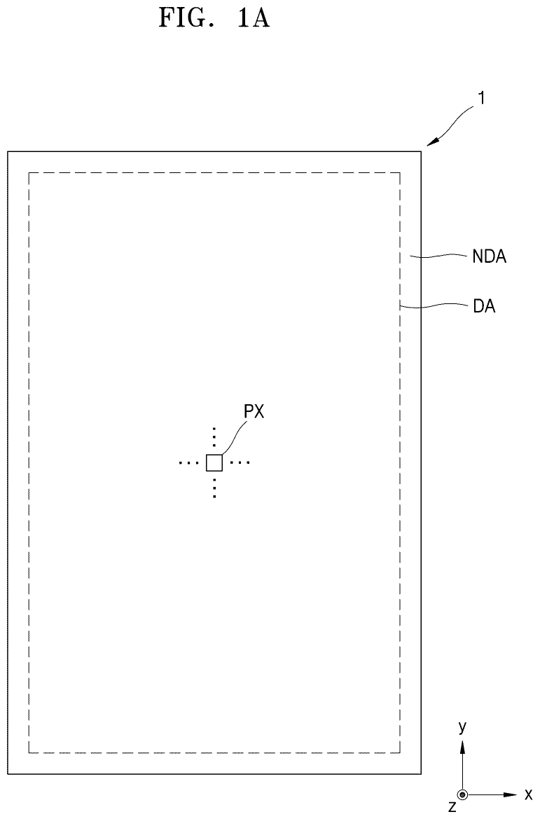

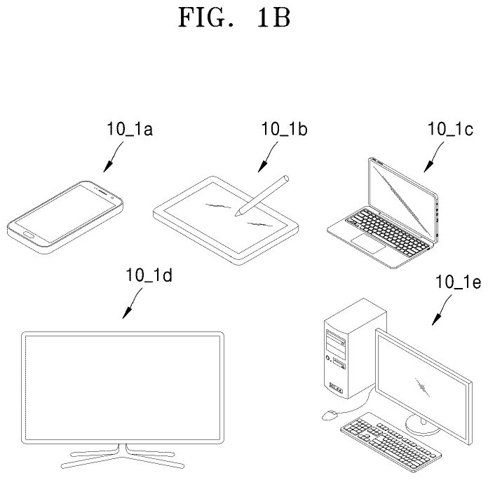

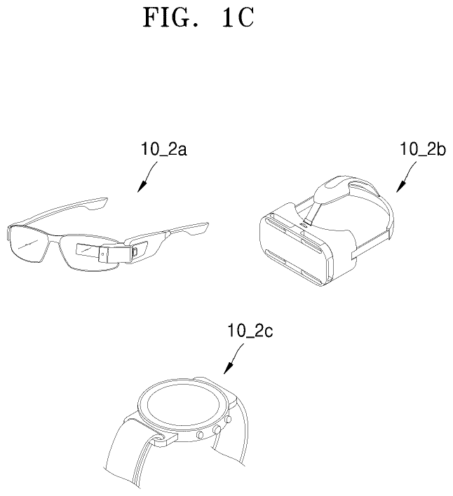

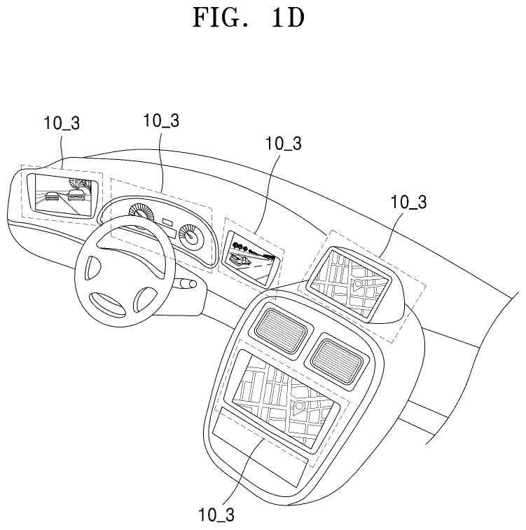

FIG. 1A is a schematic plan view illustrating a display apparatus 1 according to an embodiment.

FIG. 1B to 1D are perspective views illustrating electronic devices according to one or more embodiments.

Referring to FIG. 1A to 1D, the display apparatus 1 may include a display area DA and a non-display area NDA. In the display area DA, subpixels PX including light-emitting diodes may be arranged to provide a certain image. The non-display area NDA may be an area that does not provide an image and may surround the display area DA. In the non-display area NDA, a scan driver and a data driver that provide an electrical signal to be applied to the subpixels PX of the display area DA, and power lines for supplying power such as driving voltage and common voltage may be arranged.

Although FIG. 1A illustrates that a length of the display apparatus 1 in an x direction is less than a length in a y direction intersecting the x direction, the disclosure is not limited thereto. According to another embodiment, a shape of the display apparatus 1 may be changed in various ways, such that the length in the x direction may be greater than the length in the y direction.

The display apparatus 1 may be applied to various electronic devices such as a mobile phone 10_1a, a smart phone 10_1a, a tablet personal computer 10_1b, a mobile communication terminal, an electronic notebook, an electronic book, a portable multimedia player (PMP), a navigation device, an ultra mobile PC (UMPC), a television 10_1d, a laptop 10_1c, a monitor 10_1d or 10_1e, a billboard, and the Internet of Things (IoT). The display apparatus 1 according to an embodiment may be applied to wearable electronic devices such as a smart watch 10_2c, a watch phone, a glasses-type display 10_2a, and a head mounted display 10_2b (HMD). The display apparatus 1 according to an embodiment may be applied to electronic devices of a vehicle 10_3, such as a dashboard of a car, a center information display (CID) located on a center fascia or a dashboard of a car, a mirror display replacing a side mirror of a car, and a display screen located on a rear surface of a front seat as entertainment for backseat passengers in a car.

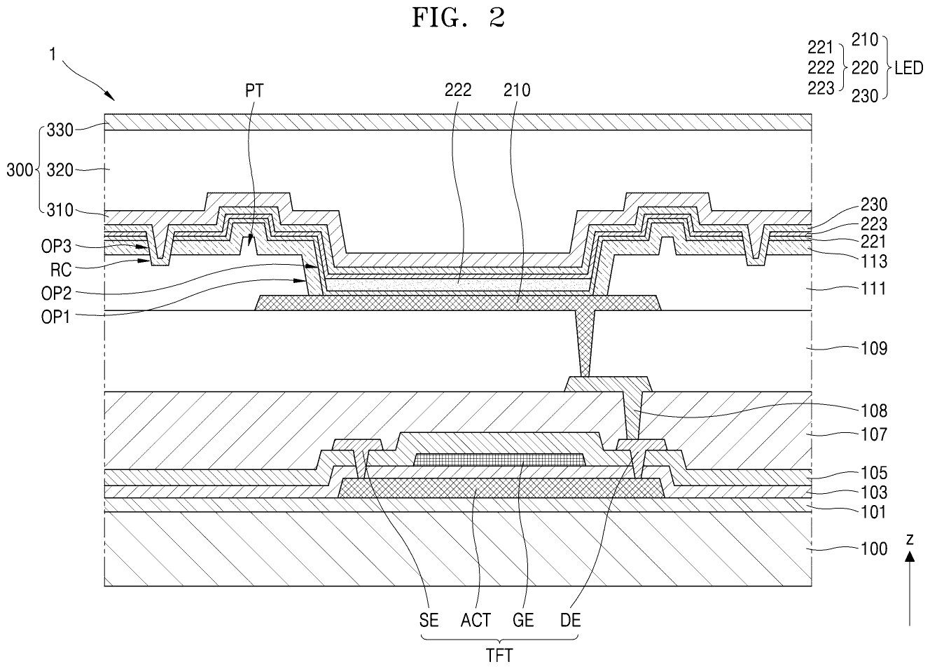

FIG. 2 is a cross-sectional view showing a portion of a display apparatus according to an embodiment.

Referring to FIG. 2, the display apparatus 1 may include light-emitting diodes LEDs as display elements. A light-emitting diode LED may be connected to a corresponding thin film transistor TFT. The thin film transistor TFT may drive the light-emitting diode LED, and the light-emitting diode LED may emit light of a certain color. According to an embodiment, the thin film transistor TFT may be a driving transistor.

The thin film transistor TFT may be located on a substrate 100. The thin film transistor TFT may include an active layer ACT, a source electrode SE, a drain electrode DE, and a gate electrode GE. The active layer ACT may include a semiconductor.

The source electrode SE, the drain electrode DE, and the gate electrode GE may each include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The source electrode SE, the drain electrode DE, and the gate electrode GE may each have a single-layer structure or a multi-layer structure.

A buffer layer 101 may be located between the active layer ACT and the substrate 100. A gate insulating layer 103 may be located between the gate electrode GE and the active layer ACT. An interlayer insulating layer 105 may be located between the source electrode SE (or drain electrode DE) and the gate electrode GE. The buffer layer 101, the gate insulating layer 103, and the interlayer insulating layer 105 may each include an inorganic insulating material such as silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ). The buffer layer 101, the gate insulating layer 103, and the interlayer insulating layer 105 may have a single-layer or a multi-layer structure.

The source electrode SE may be connected to the active layer ACT through a contact hole defined in the interlayer insulating layer 105 and the gate insulating layer 103. A region of the active layer ACT to which the source electrode SE is connected (e.g., source region) may be a region doped with an impurity (dopant). The drain electrode DE may be connected to the active layer ACT through a contact hole defined in the interlayer insulating layer 105 and the gate insulating layer 103. A region of the active layer ACT to which the drain electrode DE is connected (e.g., drain region) may be doped with an impurity (dopant). A region of the active layer ACT located between the source region and the drain region (e.g., a channel region) may be an undoped region. The gate electrode GE may overlap the channel region.

A first organic insulating layer 107 may be located on the thin film transistor TFT. The first organic insulating layer 107 may cover the thin film transistor TFT. The first organic insulating layer 107 may be a planarization layer having a flat upper surface. A contact hole overlapping the drain electrode DE may be defined in the first organic insulating layer 107. The first organic insulating layer 107 may include an organic insulating material such as acrylic, benzocyclobutene (BCB), polyimide (PI), or hexamethyldisiloxane (HMDSO), but is not necessarily limited thereto.

A contact metal 108 may be disposed on the first organic insulating layer 107. The contact metal 108 may be connected to the drain electrode DE through the contact hole defined in the first organic insulating layer 107. The contact metal 108 may include at least one selected from aluminum (Al), copper (Cu), titanium (Ti), and molybdenum (Mo). The contact metal 108 may have a single-layer or a multi-layer structure.

A second organic insulating layer 109 may be disposed on the first organic insulating layer 107. The second organic insulating layer 109 may cover the contact metal 108. The second organic insulating layer 109 may be a planarization layer having a flat upper surface. A contact hole overlapping the contact metal 108 may be defined in the second organic insulating layer 109. The second organic insulating layer 109 may include an organic insulating material such as acrylic, benzocyclobutene (BCB), polyimide (PI), or hexamethyldisiloxane (HMDSO), but is not necessarily limited thereto.

The light-emitting diode LED may be located on the second organic insulating layer 109. The light-emitting diode LED may include a pixel electrode 210, an intermediate layer 220, and a counter electrode 230. The intermediate layer 220 may include a first functional layer 221, an emission layer 222, and a second functional layer 223.

The pixel electrode 210 may be disposed on the second organic insulating layer 109. The pixel electrode 210 may be connected to the contact metal 108 through the contact hole defined in the second organic insulating layer 109. The pixel electrode 210 may be connected to the drain electrode DE through the contact metal 108 and further connected to the active layer ACT.

According to the embodiment illustrated in FIG. 2, the pixel electrode 210 is electrically connected to the thin film transistor TFT (e.g., to a drain electrode DE) through the contact metal 108. However, the disclosure is not limited thereto. According to another embodiment, the display apparatus 1 may not include the second organic insulating layer 109 and the contact metal 108 may be omitted so that the pixel electrode may be directly connected to the thin film transistor. According to another embodiment, the display apparatus 1 may include three or more organic insulating layers and may include a plurality of contact metals arranged between the respective organic insulating layers.

According to an embodiment, the pixel electrode 210 may be formed to be a reflective electrode. For example, the pixel electrode 210 may be formed by forming a reflective film by using silver (Ag), magnesium (Mg), aluminum (Al), platinum (Pt), palladium (Pd), gold (Au), nickel (Ni), neodymium (Nd), iridium (Ir), chromium (Cr), or a compound thereof, and disposing a film including ITO, IZO, ZnO, or In₂O₃ on the reflective film. According to an embodiment, the pixel electrode 210 may have a structure in which an ITO layer, an Ag layer, and an ITO layer are sequentially stacked. The disclosure is not limited thereto, and the pixel electrode may include various materials and may be modified in various ways, such as being single-layered or multi-layered.

A first bank layer 111 may be disposed on the pixel electrode 210 and the second organic insulating layer 109. In the present embodiment, the first bank layer 111 may include a light-shielding material. For example, the first bank layer 111 may include a black dye.

The first bank layer 111 may cover an edge (e.g., edge portion) of the pixel electrode 210. A first opening OP1 overlapping a central area of the pixel electrode 210 may be defined in the first bank layer 111. In other words, the first bank layer 111 may include the first opening OP1 that overlaps the central area of the pixel electrode 210. The first opening OP1 may define an emission area of the light-emitting diode LED.

The first bank layer 111 may include a protrusion PT adjacent to the first opening OP1. The protrusion PT may be located on one side of the first opening OP1 or on both sides of the first opening OP1. Although not shown in FIG. 2, according to an embodiment, the protrusion PT may surround the first opening OP1 when viewed in plan view.

The first bank layer 111 may include a recess RC adjacent to the first opening OP1. In other words, the recess RC may be defined in the first bank layer 111 adjacent to the first opening OP1. The recess RC may be located on one side of the first opening OP1 or on both sides of the first opening OP1. Although not shown in FIG. 2, according to an embodiment, the recess RC may surround the first opening OP1 when viewed in a plan view.

According to an embodiment, the protrusion PT may be located between the recess RC and the first opening OP1. According to an embodiment, the recess RC may surround the protrusion PT when viewed in a plan view. According to an embodiment, the recess RC may be located between the protrusion PT and the first opening OP1. According to an embodiment, the protrusion PT may surround the recess RC when viewed in a plan view.

A capping layer 113 may be disposed on the first bank layer 111. The capping layer 113 may include an inorganic insulating material. For example, the capping layer 113 may include a material selected from at least one of silicon oxide (SiO₂), silicon nitride (SiNₓ), and silicon oxynitride (SiON). The capping layer 113 may have a single-layer or a multi-layer structure.

The capping layer 113 may entirely cover the first bank layer 111. A second opening OP2 overlapping the first opening OP1 of the first bank layer 111 may be defined in the capping layer 113. In other words, the capping layer 113 may have the second opening OP2 overlapping the first opening OP1. A portion of the capping layer 113 may be located within the first opening OP1 of the first bank layer 111. The capping layer 113 may be in contact with an upper surface of the pixel electrode 210 within the first opening OP1.

A third opening OP3 overlapping the recess RC of the first bank layer 111 may be defined in the capping layer 113. In other words, the capping layer 113 may have the third opening OP3 overlapping the recess RC. The third opening OP3 may have a shape that is similar to that of the recess RC. The third opening OP3 may be formed to pass through the capping layer 113. In other words, the third opening OP3 may include a penetration hole.

The intermediate layer 220 may be disposed on the capping layer 113. The first functional layer 221 of the intermediate layer 220 may be disposed on the capping layer 113. A portion of the first functional layer 221 may be located within the second opening OP2. The first functional layer 221 may be in contact with the upper surface of the pixel electrode 210 within the second opening OP2. The first functional layer 221 may entirely cover the capping layer 113. The first functional layer 221 may be disconnected in an area overlapping the third opening OP3. In other words, the first functional layer 221 may include an opening overlapping the third opening OP3 and the recess RC.

The emission layer 222 may be disposed on the first functional layer 221. The emission layer 222 may be located within the second opening OP2.

The second functional layer 223 may be disposed on the first functional layer 221 and the emission layer 222. A portion of the second functional layer 223 may be located within the second opening OP2. The second functional layer 223 may be in contact with an upper surface of the emission layer 222 within the second opening OP2. The second functional layer 223 may entirely cover the first functional layer 221. The second functional layer 223 may be disconnected in an area overlapping the third opening OP3. In other words, the second functional layer 223 may include an opening overlapping the third opening OP3 and the recess RC.

The emission layer 222 may include a material that emits light of a certain color when voltage is applied. According to an embodiment, the emission layer 222 may include a light-emitting organic material. According to an embodiment, the emission layer 222 may include a light-emitting inorganic material. According to an embodiment, the emission layer 222 may include quantum dots. According to an embodiment, the first functional layer 221 may include at least one of a hole injection layer and a hole transportation layer, and the second functional layer 223 may include at least one of an electron injection layer and an electron transportation layer. According to an embodiment, the first functional layer 221 may include at least one of an electron injection layer and an electron transportation layer, and the second functional layer 223 may include at least one of a hole injection layer and a hole transportation layer.

The counter electrode 230 may be located on the second functional layer 223. The counter electrode 230 may entirely cover the intermediate layer 220. For example, the counter electrode 230 may entirely cover the second functional layer 223. The counter electrode 230 may cover the recess RC and the third opening OP3. The counter electrode 230 may partially fill each of the recess RC and the third opening OP3. The counter electrode 230 may be in contact with the first bank layer 111 and the capping layer 113.

A thin film encapsulation layer 300 may be disposed on the counter electrode 230. The thin film encapsulation layer 300 may include one or more inorganic encapsulation layers and one or more organic encapsulation layers. For example, the thin film encapsulation layer 300 may include a first inorganic encapsulation layer 310, an organic encapsulation layer 320, and a second inorganic encapsulation layer 330. According to an embodiment, the first inorganic encapsulation layer 310 may be disposed on the counter electrode 230 and may entirely cover the counter electrode 230. According to an embodiment, the second inorganic encapsulation layer 330 may be disposed on the first inorganic encapsulation layer 310. According to an embodiment, the organic encapsulation layer 320 may be located between the first inorganic encapsulation layer 310 and the second inorganic encapsulation layer 330. According to an embodiment, the second inorganic encapsulation layer 330 may entirely cover the organic encapsulation layer 320. According to an embodiment, the organic encapsulation layer 320 may be a planarization layer that planarizes a curve of an upper surface of the first inorganic encapsulation layer 310.

The first inorganic encapsulation layer 310 or the second inorganic encapsulation layer 330 may include an inorganic insulating material such as aluminum oxide (AlOₓ), titanium oxide (TiOₓ), tantalum oxide (TaOₓ), hafnium oxide (HfOₓ), zinc oxide (ZnOₓ), silicon oxide (SiOₓ), silicon nitride (SiNₓ), and silicon oxynitride (SiON). The first inorganic encapsulation layer 310 or the second inorganic encapsulation layer 330 may have a single-layer or a multi-layer structure.

The organic encapsulation layer 320 may include an organic insulating material such as polyethylene terephthalate (PET), polyethylene naphthalate (PEN), polycarbonate (PC), polyimide (PI), polyethylene sulfonate (PES), polyoxymethylene (POM), polyarylate (PAR), and hexamethyldisiloxane (HMDSO). The organic encapsulation layer 320 may have a single-layer structure or a multi-layer structure.

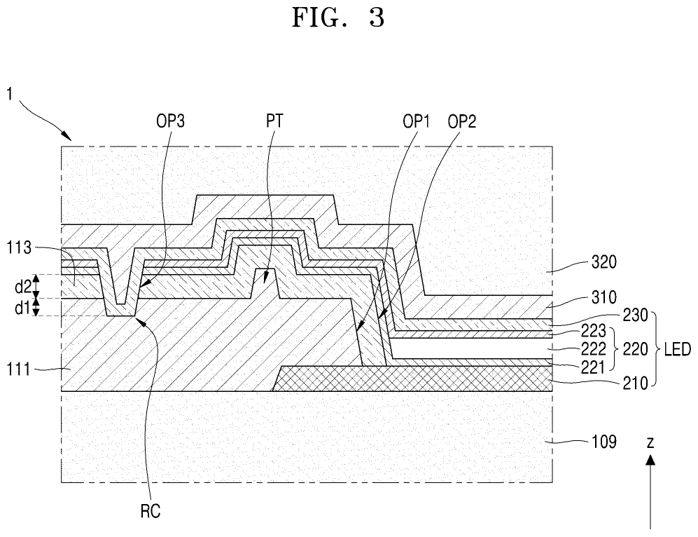

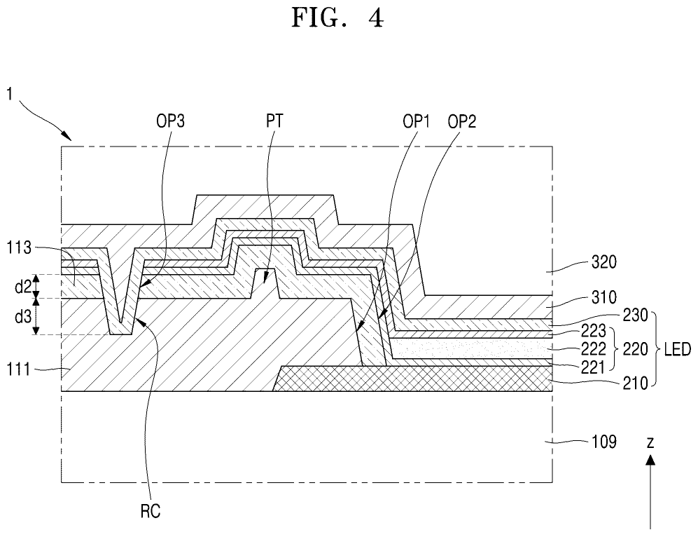

FIG. 3 is an enlarged cross-sectional view of a portion of a display apparatus according to an embodiment. FIG. 4 is an enlarged cross-sectional view of a portion of a display apparatus according to another embodiment.

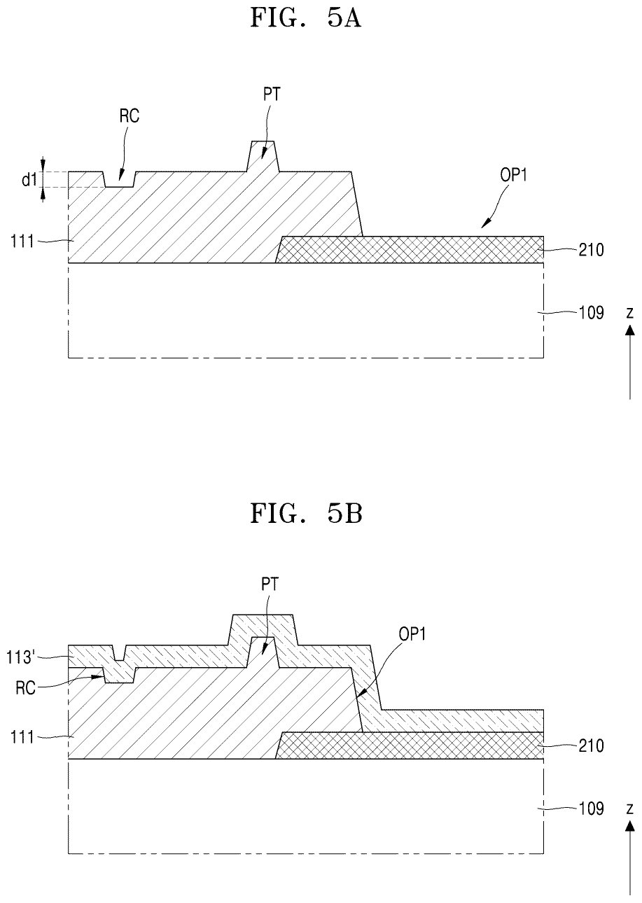

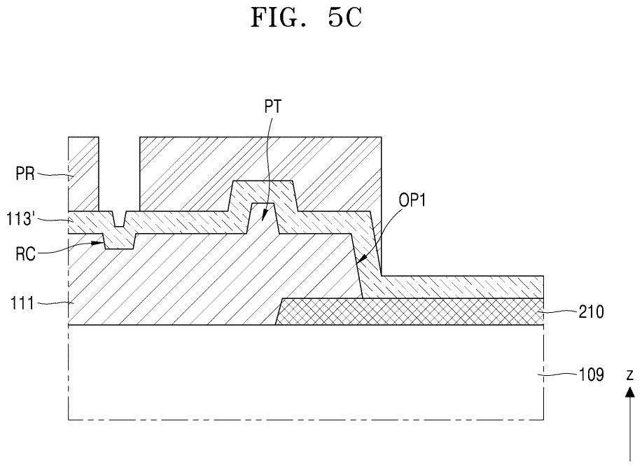

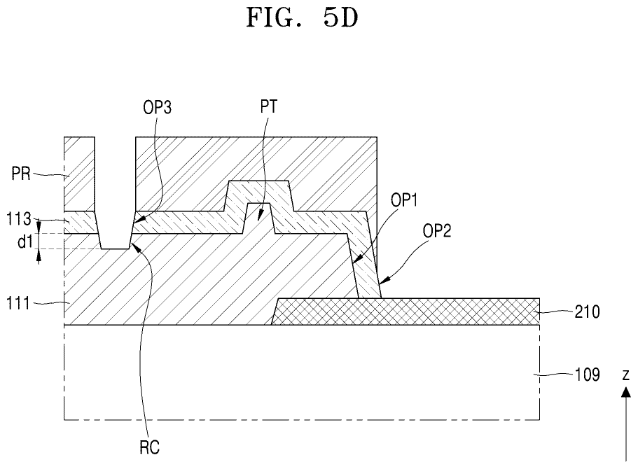

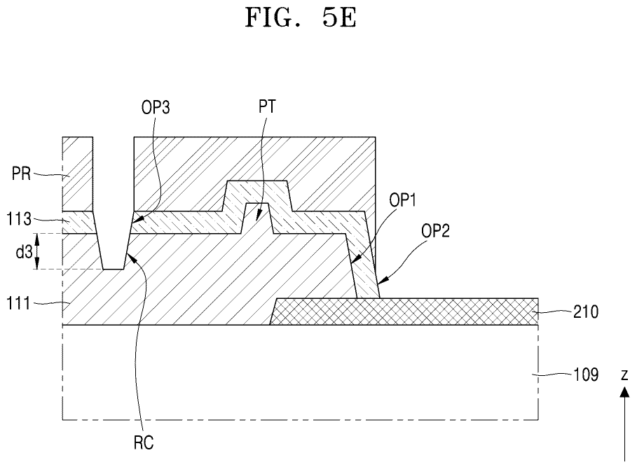

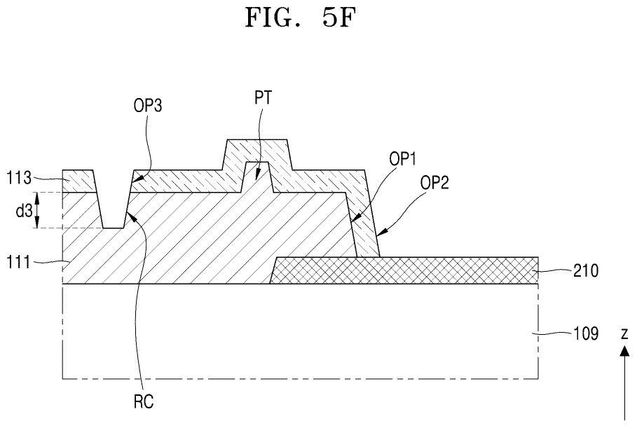

Referring to FIGS. 3 and 4 together, the recess RC may have different dimensions. In the embodiment illustrated in FIG. 3, the depth of the recess RC may be a first depth d1. In other words, the z-direction dimension of the recess RC may be the first depth d1. In the embodiment illustrated in FIG. 4, the depth of the recess RC may be a third depth d3. In other words, the z-direction dimension of the recess RC may be the third depth d3. The third depth d3 may be greater than the first depth d1. In other words, the recess RC (FIG. 4) according to the embodiment illustrated in FIG. 4 may be greater than the recess RC (FIG. 3) according to the embodiment illustrated in FIG. 3. A method of forming the recess RC such as the recess RC shown in FIG. 4, for example, a relatively deeper recess RC, is described below with reference to FIGS. 5A to 5F.

In the embodiments illustrated in FIGS. 3 and 4, the depth of the third opening OP3 may be a second depth d2. The third opening OP3 may include a penetration hole, and thus, the second depth d2 of the third opening OP3 may be equal to the thickness of the capping layer 113.

The first functional layer 221 and the second functional layer 223 may be disconnected by the recess RC and the third opening OP3 described with reference to FIGS. 2 to 4. For example, the first functional layer 221 and the second functional layer 223 may be disconnected in an area overlapping the recess RC and the third opening OP3. This may prevent lateral leakage, which is current flowing from one light-emitting diode LED to an adjacent light-emitting diode. Although not shown in FIGS. 2 to 4, in another embodiment, portions of the first functional layer 221 or the second functional layer 223 may be located within the recess RC or the third opening OP3. For example, portions of the first functional layer 221 or the second functional layer 223 may be located below the counter electrode 230 within the recess RC or the third opening OP3. In this case, a portion of each of the first functional layer 221 or the second functional layer 223 disposed within the recess RC or the third opening OP3 may be spaced apart from another portion of each of the first functional layer 221 or the second functional layer 223 disposed on the capping layer 113.

FIGS. 5A to 5F are schematic cross-sectional views illustrating a method of manufacturing a display apparatus according to an embodiment.

Referring to FIG. 5A, the first bank layer 111 may be disposed on the second organic insulating layer 109 and the pixel electrode 210. The first bank layer 111 may include the recess RC, the protrusion PT, and the first opening OP1 as described above. The first bank layer 111 may be located as a single body. The recess RC, the protrusion PT, and the first opening OP1 may be formed substantially simultaneously. For example, the recess RC, the protrusion PT, and the first opening OP1 may be formed by locating a preliminary layer to entirely cover the pixel electrode 210 and then etching the preliminary layer through a halftone mask. In this case, the remaining portion after the preliminary layer is etched may be understood as the first bank layer 111.

Referring to FIG. 5B, a first material layer 113′ may be located on the first bank layer 111. The first material layer 113′ may be located to entirely cover the first bank layer 111 and the pixel electrode 210. Therefore, the first material layer 113′ may cover a central portion of the pixel electrode 210. The first material layer 113′ may include the same material as the capping layer 113 (FIG. 2) described above.

Referring to FIG. 5C, a photoresist PR may be disposed on the first material layer 113′. The photoresist PR may include an opening overlapping the first opening OP1. The photoresist PR may include an opening overlapping the recess RC.

Referring to FIGS. 5C and 5D, a portion of the first material layer 113′ may be etched using the photoresist PR as a mask. The second opening OP2 may be formed by etching the first material layer 113′ in an area overlapping the first opening OP1. The third opening OP3 may be formed by etching the first material layer 113′ in an area overlapping the recess RC. The remaining portion after the first material layer 113′ is partially etched may be understood as the capping layer 113. In this case, the first material layer 113′ may be etched such that the third opening OP3 is formed to pass through the first material layer 113′ (or capping layer 113). In other words, the third opening OP3 may be formed as a penetration hole.

Referring to FIGS. 5D, 5E, and 5F, the dimension of the recess RC may be extended. For example, similarly to the description via comparison between FIGS. 3 and 4, the depth of the recess RC may be increased to the third depth d3. The depth of the recess RC may be increased by additionally etching the first bank layer 111. There may be several methods to increase the depth of the recess RC, for example, from the first depth d1 of FIG. 5D to the third depth d3.

In a first method, first, as illustrated in FIG. 5E, the first bank layer 111 may be additionally etched using a material for etching the first bank layer 111 (e.g., an etchant). During this process, the recess RC may become deeper (e.g. from the first depth d1 to the third depth d3). Then, the photoresist PR may be removed as shown in FIG. 5F.

In the second method, an operation illustrated in FIG. 5E may be omitted. Referring to FIGS. 5D and 5F, the photoresist PR may be removed, and simultaneously, the depth of the recess RC may be increase. In this case, a material that removes photoresist PR (e.g., a photoresist stripper) may also etch the first bank layer 111. Therefore, in a process of removing the photoresist PR using a photoresist stripper, a portion of the first bank layer 111 may be additionally removed. Accordingly, the depth of the recess RC may be increased (e.g. from the first depth d1 to the third depth d3).

A third method may be obtained by combining the first and second methods. First, the first bank layer 111 may be additionally etched using the etchant to increase the depth of the recess RC (for example, to the third depth d3). Then, the photoresist PR may be removed using the photoresist stripper, and simultaneously, the depth of the recess RC may be increased (for example, greater than the third depth d3). In this case, the recess RC with a depth greater than the depth of the recess RC illustrated in FIG. 5F (the third depth d3) may be formed.

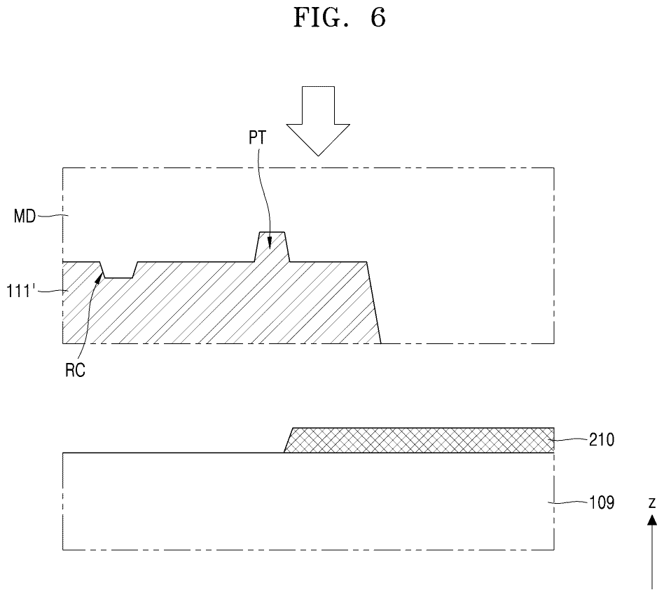

FIG. 6 is a schematic cross-sectional view illustrating an operation of a method of manufacturing a display apparatus according to an embodiment.

FIG. 6 illustrates an embodiment of a method of arranging the first bank layer 111 illustrated in FIG. 5A. Referring to FIG. 6, a second material layer 111′ may be fixed to a mold MD. The recess RC and the protrusion PT may be formed in the second material layer 111′. An opening corresponding to the first opening OP1 (FIG. 5A) may be formed in the second material layer 111′. The mold MD and the second material layer 111′ may be located such that a portion of the second material layer 111′ overlaps an edge (e.g., edge portion) of the pixel electrode 210. Then, the mold MD and the second material layer 111′ may be lowered toward the pixel electrode 210. For example, the mold MD and the second material layer 111′ may be moved toward the pixel electrode 210 in an opposite direction to the z direction.

The second material layer 111′ may come into contact with the pixel electrode 210, and then, pressure may be applied to the mold MD (e.g., in the opposite direction to the z direction). Accordingly, a portion of the second material layer 111′ may be deformed to have a shape similar to that of the edge (e.g., edge portion) of the pixel electrode 210. A portion of the second material layer 111′, which does not overlap the pixel electrode 210, may come into contact with the second organic insulating layer 109, and then, the pressure may be removed. Then, the mold MD may be removed. The second material layer 111′ that is deformed according to the shape of the edge (e.g., edge portion) of the pixel electrode 210 remaining after the mold MD is removed may be understood as a pixel definition layer 111 (FIG. 5A).

In the present embodiment, the second material layer 111′ may include a light-shielding material. For example, the second material layer 111′ may include a black dye.

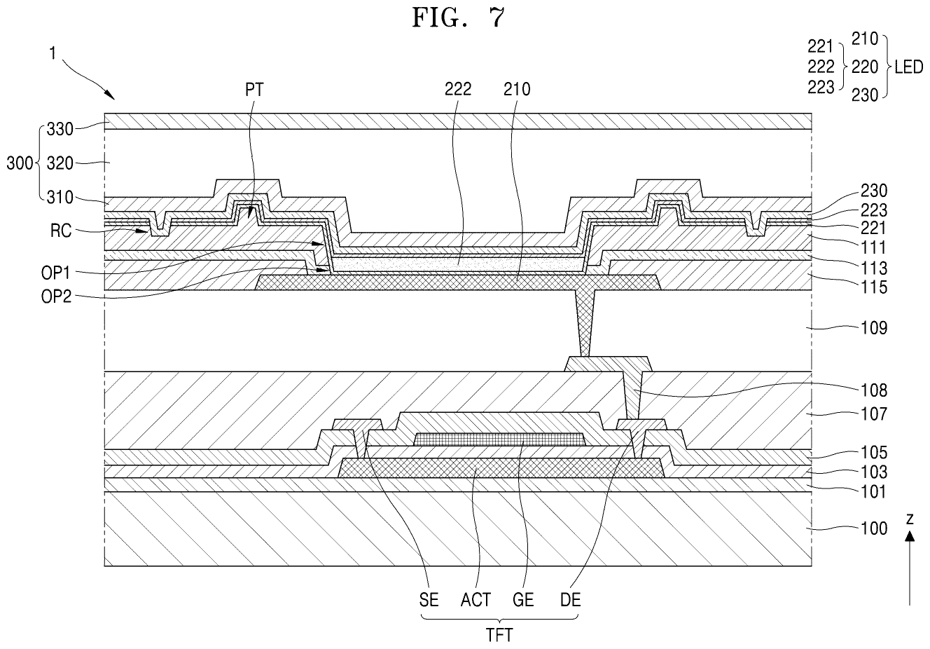

FIG. 7 is a cross-sectional view of a portion of a display apparatus according to an embodiment. Hereinafter, the description of the embodiment illustrated in FIG. 7 will be mainly given in terms of a difference from the embodiment illustrated in FIG. 2.

Referring to FIG. 7, the display apparatus 1 may include a second bank layer 115, the capping layer 113, and the first bank layer 111 that are sequentially disposed on the pixel electrode 210. The second bank layer 115 may be disposed on the pixel electrode 210. The capping layer 113 may be disposed on the second bank layer 115. That is, the second bank layer 115 may be disposed below the capping layer 113. The first bank layer 111 may be disposed on the capping layer 113. That is, the capping layer 113 may be disposed below the first bank layer 111.

The second bank layer 115 may cover the edge (e.g., edge portion) of the pixel electrode 210. An opening overlapping the central portion of the pixel electrode 210 may be defined in the second bank layer 115.

The capping layer 113 may entirely cover the second bank layer 115. The second opening OP2 overlapping the central portion of the pixel electrode 210 may be defined in the capping layer 113. In other words, the capping layer 113 may have the second opening OP2 overlapping the central portion of the pixel electrode 210. The capping layer 113 may cover a lateral surface of the second bank layer 115, which defines the opening of the second bank layer 115. The capping layer 113 may be in contact with the upper surface of the pixel electrode 210.

The first bank layer 111 may cover the upper surface of the capping layer 113. The first opening OP1 overlapping the second opening OP2 may be defined in the first bank layer 111. In other words, the first bank layer 111 may have the first opening OP1 overlapping the second opening OP2. The first bank layer 111 may not cover the lateral surface of the capping layer 113, which defines the second opening OP2. The first bank layer 111 may be spaced apart from the upper surface of the pixel electrode 210. The capping layer 113 may be located between a lower surface of the first bank layer 111 and the upper surface of the pixel electrode 210. The recess RC and the protrusion PT may be defined in the first bank layer 111. In other words, the first bank layer 111 may have the recess RC and the protrusion PT. The characteristics of the recess RC and the protrusion PT of the first bank layer 111 illustrated in FIG. 7 may be substantially the same as the characteristics of the recess RC and the protrusion PT of the first bank layer 111 (FIG. 2) described with reference to FIG. 2.

The intermediate layer 220, the counter electrode 230, and the thin film encapsulation layer 300 may be sequentially arranged on the first bank layer 111.

In the present embodiment, the second bank layer 115 may include a light-shielding material. For example, the second bank layer 115 may include a black dye. In the present embodiment, the capping layer 113 may include an inorganic insulating material. For example, the capping layer 113 may include silicon oxide SiO₂ or silicon nitride SiNₓ. In the present embodiment, the first bank layer 111 may include an organic insulating material. For example, the first bank layer 111 may include polyimide (PI).

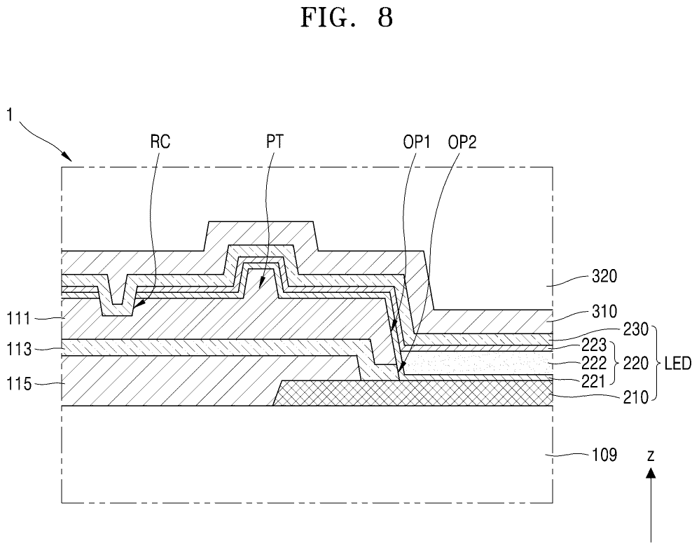

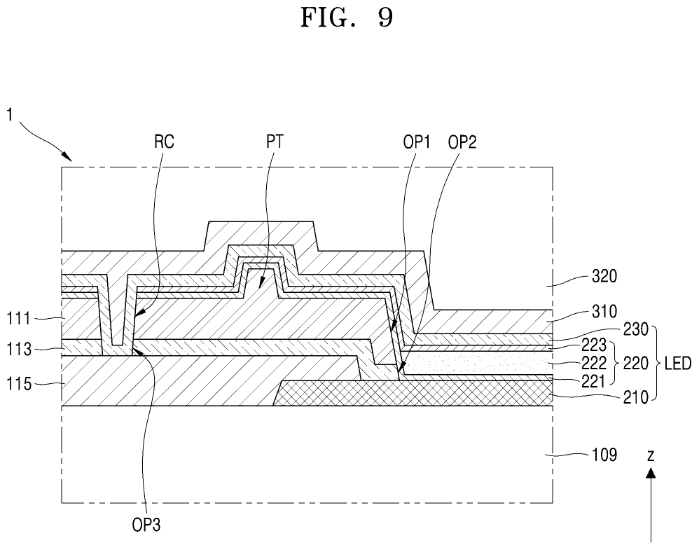

FIG. 8 is an enlarged cross-sectional view of a portion of a display apparatus according to an embodiment. FIG. 9 is an enlarged cross-sectional view of a portion of a display apparatus according to another embodiment. FIG. 10 is an enlarged cross-sectional view of a portion of a display apparatus according to another embodiment.

Referring to FIG. 8, the recess RC of the first bank layer 111 may include a blind hole that is not formed to pass through the first bank layer 111.

Referring to FIG. 9, the recess RC of the first bank layer 111 may include a penetration hole that is formed to pass through the first bank layer 111. The third opening OP3 overlapping the recess RC may be defined in the capping layer 113. In other words, the capping layer 113 may have the third opening OP3 overlapping the recess RC. The third opening OP3 may include a penetration hole formed to pass through the capping layer 113.

Referring to FIG. 10, the recess RC may be formed to pass through the first bank layer 111, and the third opening OP3 may be formed to pass through the capping layer 113. A groove GR overlapping the recess RC and the third opening OP3 may be defined in the second bank layer 115. In other words, the second bank layer 115 may have the groove GR overlapping the recess RC and the third opening OP3.

An embodiment in which the recess RC is formed as a penetration hole and no opening is formed in the capping layer 113 may also fall within the scope of the disclosure. An embodiment in which the recess RC is formed as a penetration hole and the third opening OP3 is formed as a blind hole, i.e., the recess RC is formed to pass through the first bank layer 111 and the third opening OP3 is not formed to pass through the capping layer 113 may also fall within the scope of the disclosure.

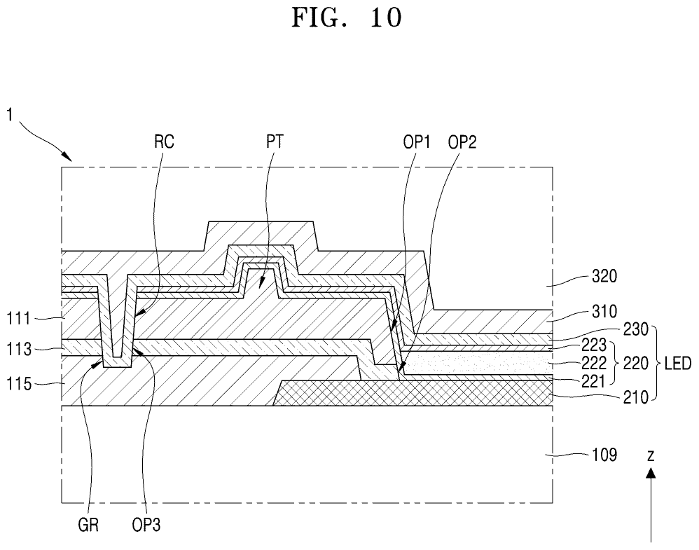

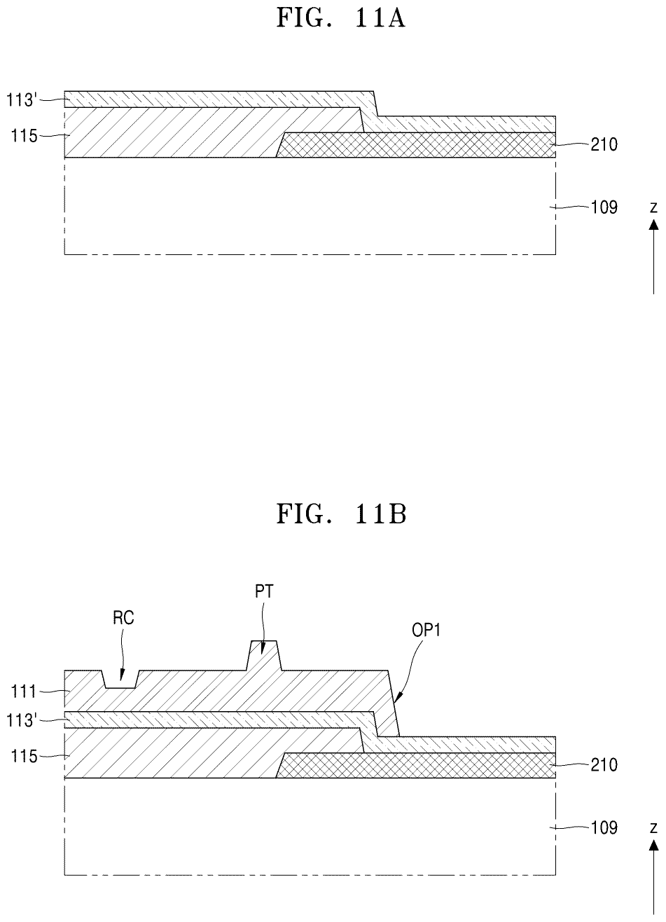

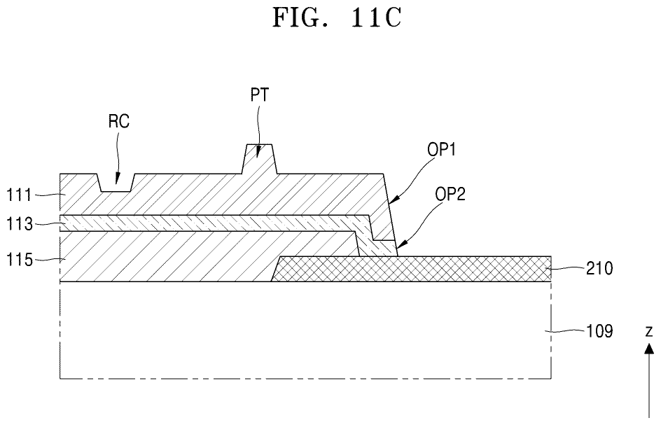

FIGS. 11A to 11C are schematic cross-sectional views illustrating a method of manufacturing a display apparatus according to an embodiment.

Referring to FIG. 11A, the second bank layer 115 may be disposed on the pixel electrode 210. The second bank layer 115 may be opened in an area overlapping the central portion of the pixel electrode 210. The first material layer 113′ may be located to entirely cover the second bank layer 115 and the pixel electrode 210. The first material layer 113′ may include the same material as the capping layer 113 (FIG. 7) described above. The first material layer 113′ may cover the central portion of the pixel electrode 210.

Referring to FIG. 11B, the first bank layer 111 may be disposed on the first material layer 113′. The first bank layer 111 may include the recess RC, the protrusion PT, and the first opening OP1. The recess RC, the protrusion PT, and the first opening OP1 may be formed substantially simultaneously. For example, the recess RC, the protrusion PT, and the first opening OP1 may be formed by locating a preliminary layer to entirely cover the first material layer 113′ and then etching the preliminary layer through a halftone mask. In this case, the remaining portion after the preliminary layer is etched may be understood as the first bank layer 111.

Referring to FIGS. 11B and 11C, a portion of the first material layer 113′ may be etched using the first bank layer 111 as a mask. The second opening OP2 may be formed by etching the first material layer 113′ in an area overlapping the first opening OP1. The remaining portion after the first material layer 113′ is partially etched may be understood as the capping layer 113. In this case, the first material layer 113′ may be etched such that the second opening OP2 is formed to pass through the first material layer 113′ (or capping layer 113).

The embodiment illustrated in FIG. 8 may be implemented through the method of manufacturing the display apparatus illustrated in FIGS. 11A to 11C.

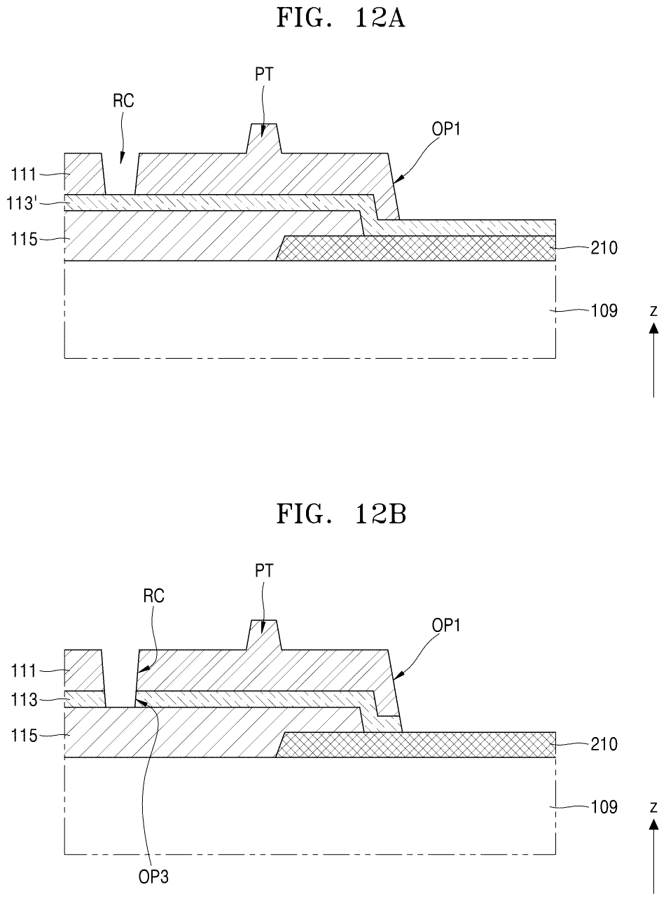

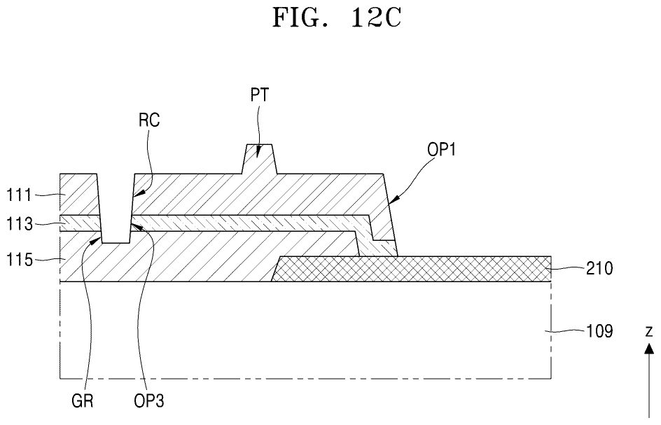

FIGS. 12A to 12C are schematic cross-sectional views illustrating a method of manufacturing a display apparatus according to another embodiment.

Referring to FIG. 12A, the first material layer 113′ and the first bank layer 111 may be disposed on the pixel electrode 210. In the present embodiment, the recess RC of the first bank layer 111 may be formed to pass through the first bank layer 111. Therefore, a portion of the upper surface of the first material layer 113′, which overlaps the recess RC may be exposed.

Referring to FIGS. 12A and 12B, a portion of the first material layer 113′ may be etched using the first bank layer 111 as a mask. The second opening OP2 may be formed by etching the first material layer 113′ in an area overlapping the first opening OPL. The recess RC may be formed to pass through the first bank layer 111 and the upper surface of the first material layer 113′ may be exposed in an area overlapping the recess RC, and thus, the first material layer 113′ may be etched in the corresponding area. Accordingly, the third opening OP3 may be formed by etching the first material layer 113′ in an area overlapping the recess RC. The remaining portion after the first material layer 113′ is partially etched may be understood as the capping layer 113. In this case, the first material layer 113′ may be etched such that the second opening OP2 and the third opening OP3 are formed to pass through the first material layer 113′ (or capping layer 113).

Referring to FIG. 12C, optionally, the second bank layer 115 may be additionally etched. In other words, the groove GR overlapping the recess RC and the third opening OP3 may be formed in the second bank layer 115.

When the operation illustrated in FIG. 12C is not performed, the embodiment illustrated in FIG. 9 may be implemented. When the operation illustrated in FIG. 12C is performed, the embodiment illustrated in FIG. 10 may be implemented.

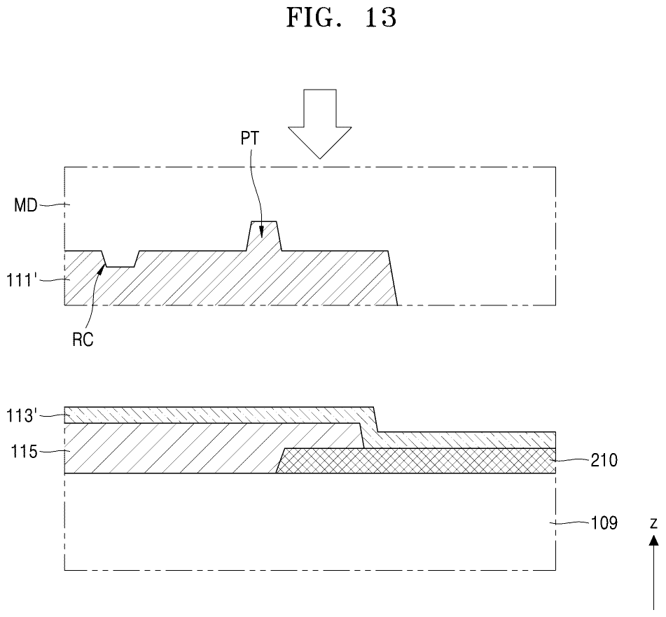

FIG. 13 is a schematic cross-sectional view illustrating an operation of a method of manufacturing a display apparatus according to an embodiment.

FIG. 13 illustrates an embodiment of a method of arranging the first bank layer 111 illustrated in FIG. 11A. Referring to FIG. 13, the second material layer 111′ may be fixed to the mold MD. The recess RC and the protrusion PT may be formed in the second material layer 111′. An opening corresponding to the first opening OP1 (FIG. 11A) may be formed in the second material layer 111′. The mold MD and the second material layer 111′ may be located such that a portion of the second material layer 111′ overlaps the edge (e.g., edge portion) of the pixel electrode 210. Then, the mold MD and the second material layer 111′ may be lowered toward the first material layer 113′. For example, the mold MD and the second material layer 111′ may be moved toward the first material layer 113′ in an opposite direction to the z direction.

The second material layer 111′ may come into contact with the first material layer 113′, and then, pressure may be applied to the mold MD (e.g., in the opposite direction to the z direction). Accordingly, a portion of the second material layer 111′ may be deformed to have a shape similar to that of the edge of the first material layer 113′. For example, the second material layer 111′ may be deformed similarly to a step difference of the first material layer 113′ formed by the shape of the edge of the pixel electrode 210. The second material layer 111′ may come into contact with a portion of the first material layer 113′ located below the step difference (i.e., in the opposite direction to the z direction), and then, the pressure may be removed. Then, the mold MD may be removed. The second material layer 111′, which is deformed according to the step difference of the first material layer 113′ remaining after the mold MD is removed may be understood as the first bank layer 111 (FIG. 11A).

The embodiment illustrated in FIG. 12A may be implemented by performing the process described above using the second material layer 111′ having the recess RC (see FIG. 12A) formed to pass through the second material layer 111′.

In the present embodiment, the second bank layer 115 may include a light-shielding material. For example, the second bank layer 115 may include a black dye. In the present embodiment, the first material layer 113′ may include an inorganic insulating material. For example, the first material layer 113′ may include silicon oxide SiO₂ or silicon nitride SiNₓ. In the present embodiment, the second material layer 111′ may include an organic insulating material. For example, the second material layer 111′ may include polyimide (PI).

As such, the disclosure has been described with reference to the embodiments shown in the drawings, but this is only exemplary, and those skilled in the art will understand that various modifications and equivalent other embodiments are possible therefrom. Therefore, the true technical scope of the disclosure should be determined by the technical spirit of the appended claims.

The display apparatus according to the described as described above may include a capping layer disposed above or below the first bank layer. When the capping layer is disposed on the first bank layer, the capping layer may enable the recess and the protrusion to be formed in the intended shapes and dimensions when forming the first bank layer. When the capping layer is disposed below the first bank layer, the adhesive force between the capping layer and the pixel electrode may be greater than the adhesive force between the first bank layer and the pixel electrode, and thus, a lifting phenomenon between the first bank layer and the pixel electrode may be prevented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a pixel electrode disposed on the substrate;
a first bank layer disposed on the pixel electrode, and having a first opening overlapping a central portion of the pixel electrode and a protrusion and a recess that are adjacent to the first opening;
a capping layer disposed above or below the first bank layer and having a second opening overlapping the first opening of the first bank layer;
an intermediate layer disposed on the pixel electrode and the first bank layer and including at least one emission layer and at least one functional layer; and
a counter electrode disposed on the intermediate layer.

2. The display apparatus of claim 1, wherein the capping layer is disposed on the first bank layer, and
the capping layer has a third opening overlapping the recess of the first bank layer.

3. The display apparatus of claim 2, wherein the third opening crosses the capping layer in a thickness direction of the capping layer.

4. The display apparatus of claim 2, wherein the capping layer is in contact with an upper surface of the pixel electrode within the first opening of the first bank layer.

5. The display apparatus of claim 2, wherein the first bank layer includes a light-shielding material, and the capping layer includes an inorganic insulating material.

6. The display apparatus of claim 1, wherein the capping layer is disposed below the first bank layer, and
the display apparatus further includes a second bank layer disposed below the capping layer.

7. The display apparatus of claim 6, wherein the second bank layer covers an edge of the pixel electrode, and the capping layer entirely covers the second bank layer.

8. The display apparatus of claim 6, wherein an edge of the capping layer, defining the second opening, is in contact with an upper surface of the pixel electrode, and an edge of the first bank layer, the edge defining the first opening, is spaced apart from the upper surface of the pixel electrode.

9. The display apparatus of claim 6, wherein the recess crosses the first bank layer in a thickness direction of the first bank layer, and the capping layer has a third opening overlapping the recess.

10. The display apparatus of claim 6, wherein the second bank layer includes a light-shielding material, and the capping layer includes an inorganic insulating material.

11. A method of manufacturing a display apparatus, the method comprising:
disposing a pixel electrode on a substrate;
forming, on the pixel electrode, a first bank layer having a first opening overlapping a central portion of the pixel electrode and a protrusion and a recess that are adjacent to the first opening; and
forming, above or below the first bank layer, a capping layer having a second opening overlapping the first opening of the first bank layer,
wherein the first opening, the protrusion, and the recess of the first bank layer are formed substantially simultaneously.

12. The method of claim 11, wherein the capping layer is formed on the first bank layer, and
the method further includes forming a third opening overlapping the recess, in the capping layer.

13. The method of claim 12, wherein the capping layer is formed to cover an edge of the first bank layer, the edge defining the first opening.

14. The method of claim 12, wherein the third opening crosses the capping layer in a thickness direction of the capping layer, and
the method further includes extending the recess of the first bank layer in a thickness direction of the first bank layer.

15. The method of claim 11, wherein the capping layer is formed below the first bank layer, and
the method further includes forming a second bank layer below the capping layer.

16. The method of claim 15, wherein the second bank layer covers an edge of the pixel electrode, and the capping layer entirely covers the second bank layer.

17. The method of claim 15, wherein an edge of the capping layer, defining the second opening, is in contact with an upper surface of the pixel electrode, and an edge of the first bank layer, the edge defining the first opening, is spaced apart from the upper surface of the pixel electrode.

18. The method of claim 15, wherein the recess is formed across the first bank layer in a thickness direction of the first bank layer, and
the method further includes forming a third opening overlapping the recess, in the capping layer.

19. The method of claim 18, wherein the third opening is formed across the capping layer in a thickness direction of the capping layer, and
the method further includes forming a groove overlapping the recess and the third opening in the second bank layer.

20. The method of claim 11, wherein the forming of the first bank layer includes pressing the first bank layer attached to a mold onto the pixel electrode.

21. An electronic device comprising a display apparatus,
wherein the display apparatus comprises:
a substrate;
a pixel electrode disposed on the substrate;
a first bank layer disposed on the pixel electrode, and having a first opening overlapping a central portion of the pixel electrode and a protrusion and a recess that are adjacent to the first opening;
a capping layer disposed above or below the first bank layer and having a second opening overlapping the first opening of the first bank layer;
an intermediate layer disposed on the pixel electrode and the first bank layer and including at least one emission layer and at least one functional layer; and
a counter electrode disposed on the intermediate layer.
